(19) United States
(12) Patent Application Publication
(10) Pub. No.: US 2025/0212571 A1
(43) Pub. Date: Jun. 26, 2025

(54) DISPLAY DEVICE

(71) Applicant: AUO Corporation, Hsinchu City (TW)

(72) Inventors: Shih-Hua LU, Hsinchu City (TW); Tzu-Hsuan YANG, Hsinchu City (TW); Chao-Chien CHIU, Hsinchu City (TW)

(21) Appl. No.: 18/914,648

(22) Filed: Oct. 14, 2024

(30) Foreign Application Priority Data
Dec. 21, 2023 (TW) 112150168

(51) Int. Cl. H01L 33/60; H01L 25/16; H01L 33/54

(52) U.S. Cl. CPC H10H 20/856; H01L 25/167; H10H 20/853

(57) ABSTRACT

A display device includes an array substrate, a first organic layer, a second organic layer, a third organic layer, and a plurality of micro lenses. The array substrate has a plurality of light-emitting elements disposed thereon. The first organic layer is on the array substrate and covers the light-emitting elements. The second organic layer is on the first organic layer. The third organic layer is on the second organic layer. The third organic layer has a portion extending downward through the second organic layer. The micro lenses are over the third organic layer and disposed corresponding to the light-emitting elements, respectively.

### CROSS-REFERENCE TO RELATED APPLICATION

This application claims priority to Taiwan Application Serial Number 112150168, filed Dec. 21, 2023, which is herein incorporated by reference.

### BACKGROUND

### Technical Field

The present disclosure relates to a display device.

### Description of Related Art

Light-emitting diodes (LED) offer excellent stability and longevity, along with benefits such as low energy consumption, high resolution, and high color saturation. Consequently, they are widely used in the backplanes of display devices. To improve light extraction efficiency, the light-emitting diode array on the backplane may be equipped with micro lens structures to collimate the light. However, residual tensile stresses may be present in the thick coppers and focusing layers for the micro lens structures in the backplanes. The accumulation of the stresses may lead to device warpage, which can impede subsequent manufacturing processes.

Accordingly, how to provide a display device to solve the aforementioned problems becomes an important issue to be solved by those in the industry.

### SUMMARY

An aspect of the disclosure is to provide a display device that may efficiently solve the aforementioned problems.

According to an embodiment of the disclosure, a display device includes an array substrate, a first organic layer, a second organic layer, a third organic layer, and a plurality of micro lenses. The array substrate has a plurality of light-emitting elements disposed thereon. The first organic layer is on the array substrate and covers the light-emitting elements. The second organic layer is on the first organic layer. The third organic layer is on the second organic layer. The third organic layer has a portion extending downward through the second organic layer. The micro lenses are over the third organic layer and disposed corresponding to the light-emitting elements, respectively.

In an embodiment of the disclosure, the display device further includes a first insulating layer covering the second organic layer. The first insulating layer is between the second organic layer and the third organic layer and between the portion of the third organic layer and the first organic layer.

In an embodiment of the disclosure, the display device further includes a pattern layer on the first insulating layer. The pattern layer has a plurality of annular patterns. The annular patterns have a plurality of openings, respectively. Each of the openings has an inner diameter smaller than a diameter of at least one of the micro lenses. Each of the annular patterns includes a first light-absorbing layer and a light-reflecting layer. The first light-absorbing layer is over the first insulating layer. The light-reflecting layer is on the first light-absorbing layer.

In an embodiment of the disclosure, each of the annular patterns further includes a second light-absorbing layer on the light-reflecting layer.

In an embodiment of the disclosure, the annular patterns extend downward from an upper surface of the first insulating layer along a plurality of sidewalls of the first insulating layer. The openings of the annular patterns correspond to the light-emitting elements, respectively.

In an embodiment of the disclosure, the display device further includes a fourth organic layer on the third organic layer. The fourth organic layer has a portion extending downward through the third organic layer.

In an embodiment of the disclosure, the display device further includes a second insulating layer covering the third organic layer. The second insulating layer is between the third organic layer and the fourth organic layer and between the portion of the fourth organic layer and the second organic layer.

In an embodiment of the disclosure, an orthographic projection area of the portion of the third organic layer projected onto the array substrate is separated from an orthographic projection area of the portion of the fourth organic layer projected onto the array substrate.

In an embodiment of the disclosure, the array substrate includes a circuit substrate, a first passivation layer, a first metal layer, a second passivation layer, a second metal layer, and a third passivation layer. The first passivation layer is on the circuit substrate. The first metal layer is on the first passivation layer. The first metal layer has a portion extending downward through the first passivation layer and electrically connected to the circuit substrate. The second passivation layer covers the first metal layer and the first passivation layer. The second metal layer is on the second passivation layer. The second metal layer has a portion extending downward through the second passivation layer and electrically connected to the first metal layer. The third passivation layer covers the second metal layer and has a portion extending downward through the second passivation layer.

In an embodiment of the disclosure, the array substrate further includes a first insulating layer covering the second passivation layer. The first insulating layer is between the second passivation layer and the third passivation layer and between the portion of the third passivation layer and the first passivation layer.

According to another embodiment of the disclosure, a display device includes an array substrate, a focusing layer, and a micro lens. The array substrate has a light-emitting element disposed thereon. The focusing layer is over the array substrate. The focusing layer includes a first organic layer, a second organic layer, and a third organic layer. The first organic layer covers the light-emitting element. The second organic layer is over the first organic layer. The second organic layer has a plurality of portions separated from one another. The third organic layer is over the second organic layer. The third organic layer has an extending portion between two adjacent ones of the portions of the second organic layer. The micro lens is over the third organic layer and over the light-emitting element.

In an embodiment of the disclosure, the extending portion of the third organic layer is in contact with the first organic layer.

In an embodiment of the disclosure, the focusing layer further includes a first insulating layer covering the second organic layer. The first insulating layer is between the portions of the second organic layer and the extending portion of the third organic layer.

In an embodiment of the disclosure, the first insulating layer is partially in contact with the first organic layer.

In an embodiment of the disclosure, the focusing layer further includes a first pattern layer on the first insulating layer. The first pattern layer has an annular pattern. The annular pattern has an inner diameter smaller than a diameter of the micro lens.

In an embodiment of the disclosure, the annular pattern of the first pattern layer extends downward from an upper surface of the first insulating layer along a sidewall of the first insulating layer.

In an embodiment of the disclosure, the focusing layer further includes a second pattern layer over the third organic layer. The second pattern layer has an annular pattern. The annular pattern of the second pattern layer has an inner diameter smaller than the diameter of the micro lens and greater than the inner diameter of the annular pattern of the first pattern layer.

Accordingly, in the display device of some embodiments of the present disclosure, the focusing layer includes a plurality of layers of thin films formed through a series of processes. At least one discontinuous film structure is included in the focusing layer, thereby reducing residual tensile stresses developed in the focusing layer due to the manufacturing processes without affecting the optical properties of the focusing layer. At the same time, an insulating layer with compressive stresses may be disposed in the focusing layer to further offset the residual tensile stresses. Compared with common display devices, the display device of some embodiments of the present disclosure may experience reduced tensile stresses while maintaining the required thickness of the focusing layer, avoiding warpage of the display device.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a partial cross-sectional view of a display device according to some embodiments of the present disclosure;

FIG. 1B is a partial top view of a display device according to some embodiments of the present disclosure;

FIG. 2 is a partial cross-sectional view of a display device according to some embodiments of the present disclosure;

FIG. 3A is a partial cross-sectional view of a display device according to some embodiments of the present disclosure;

FIG. 3B is a partial enlarged view of a square 3B of a display device in FIG. 3A according to some embodiments of the present disclosure;

FIG. 3C is a partial top view of a display device according to some embodiments of the present disclosure;

FIG. 4A is a partial cross-sectional view of a display device according to some other embodiments of the present disclosure;

FIG. 4B is a partial enlarged view of a square 4B of a display device in FIG. 4A according to some other embodiments of the present disclosure;

FIG. 4C is a partial top view of a display device according to some other embodiments of the present disclosure;

FIG. 5 is a partial cross-sectional view of a display device according to some embodiments of the present disclosure; and

FIG. 6 is a partial cross-sectional view of an array substrate according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the manufacturing processes of some display devices, array substrates such as thin film transistor (TFT) array substrates may be used to produce backplanes equipped with a micro light-emitting diode (micro LED) array and a micro lens array assembly. However, thick coppers (usually having thicknesses greater than about 500 nm) included in the backplanes may generate residual tensile stresses during deposition and processing. For example, a residual tensile stress of about 350 MPa may exist in a thick copper with a thickness of about 700 nm.

At the same time, depending on the focal length of the micro lens array, focusing layers with certain thicknesses may be required. The focusing layers are usually made of organic materials. As a result, residual stresses may also be generated in the focusing layers during the manufacturing process. For example, a positive photoresist layer of acrylic series materials with a film thickness of about 10 μm formed by a single process may have a residual tensile stress of about 34.4 MPa, while a negative photoresist layer of acrylic series materials with a film thickness of about 10 μm formed by a single process may have a residual tensile stress of about 7.3 MPa.

Thus, the superposition of tensile stresses of the backplanes and the focusing layers may cause severe warpage of large display devices. In particular, when the degree of warpage is greater than about 0.8 mm, it will be inappropriate to proceed to the subsequent manufacturing process.

Accordingly, some embodiments of the present disclosure aim to reduce the residual tensile stresses in the focusing layer by forming a plurality of organic layers with a discontinuous film structure as the focusing layer. Furthermore, in some embodiments, film layers with compressive stresses, for example, insulating layers of specific materials may be disposed between the organic layers to offset the residual tensile stresses and reduce warping.

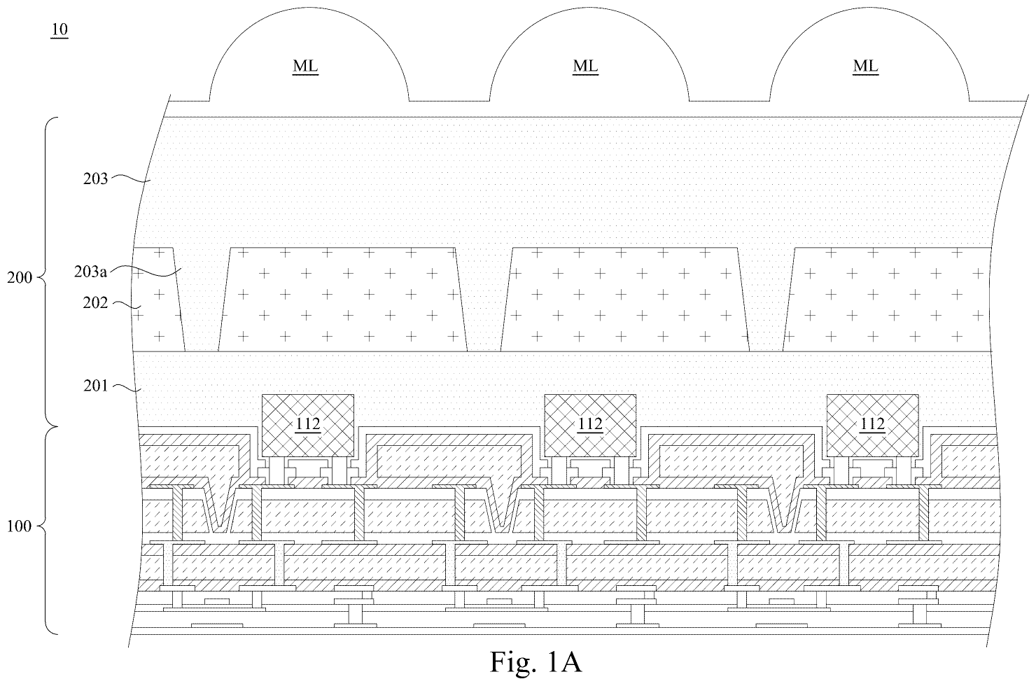

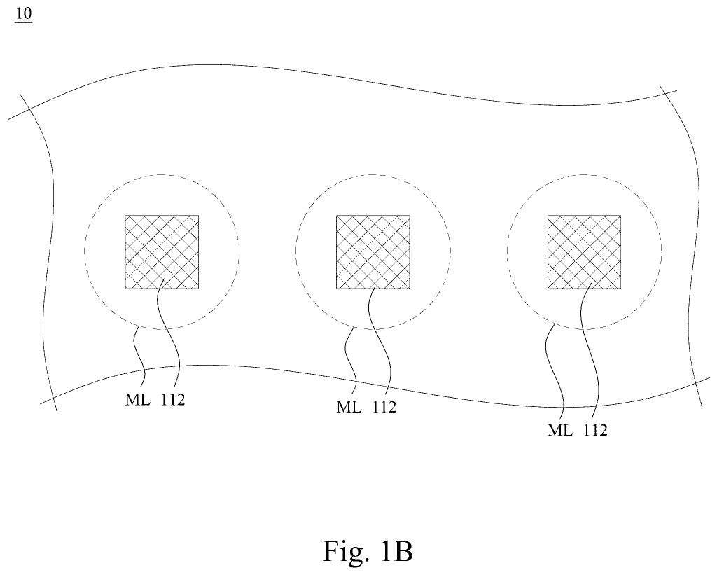

Reference is made to FIG. 1A and FIG. 1B. FIG. 1A and FIG. 1B are a partial cross-sectional view and a partial top view of a display device 10 according to some embodiments of the present disclosure, respectively. As shown in FIG. 1A, the display device 10 includes an array substrate 100, a focusing layer 200, and a plurality of micro lenses ML. The array substrate 100 has, for example, three light-emitting elements 112 disposed thereon. The focusing layer 200 is on the array substrate 100 and covers the three light-emitting elements 112. The micro lenses ML are on the focusing layer 200.

In some embodiments, as shown in FIG. 1A, the focusing layer 200 includes a first organic layer 201, a second organic layer 202, and a third organic layer 203. The first organic layer 201 is on the array substrate 100 and covers the three light-emitting elements 112. The first organic layer 201 also serves as a planarization layer. In some embodiments, the first organic layer 201 is in contact with a plurality of top surfaces and sidewalls of the three light-emitting elements 112. In some embodiments, the first organic layer 201 extends and fills the space between two pins of each of the three light-emitting elements 112.

As shown in FIG. 1A, the second organic layer 202 is on the first organic layer 201. The second organic layer 202 has a discontinuous film structure. In other words, the second organic layer 202 has a plurality of portions separated from one another on the first organic layer 201. In terms of the manufacturing process, the second organic layer 202 may be formed by patterning an organic layer fully covering the first organic layer 201. By disposing the second organic layer 202 as a discontinuous film structure, residual stresses inside the organic materials may be released.

As shown in FIG. 1A, a third organic layer 203 is on the second organic layer 202. The third organic layer 203 has a plurality of extending portions 203a. The extending portions 203a extend downward through the second organic layer 202. The third organic layer 203 may be further in contact with the first organic layer 201. In other words, each of the extending portions 203a is between two adjacent portions of the second organic layer 202. Accordingly, the first organic layer 201 and the third organic layer 203 jointly cover the second organic layer 202. Besides, the third organic layer 203 also serves as a planarization layer to prevent the micro lenses ML from being deformed due to the undulation of the third organic layer 203 and affecting the collimation of the light emitted.

In some embodiments, the first organic layer 201, the second organic layer 202, and the third organic layer 203 include acrylic series materials (i.e., acrylic organic materials), such as a negative photoresist of acrylic series materials. In some embodiments, the micro lenses ML may also include acrylic series materials, such as a positive photoresist of acrylic series materials.

It should be noted that in the drawings of the present disclosure, in order to distinguish between the organic layers, different hatch patterns are used to mark the adjacent organic layers. However, in the same embodiment, the organic layers of the focusing layer 200 are all made of the same material to avoid changes in optical properties due to film discontinuity or delamination. For example, as shown in FIG. 1A, the first organic layer 201 and the third organic layer 203 are hatched using black dots on a white background, and the separated portions of the second organic layer 202 are hatched using black crosses on a white background. However, they all contain the same material.

On the other hand, thicknesses of the organic layers also affect the level of the residual stresses existing in the organic layers. Therefore, by forming the focusing layer 200 through a series of processes, the overall residual tensile stress in the focusing layer 200 may be mitigated. One skilled in the art can adjust the number of the organic layers of the focusing layer 200 and the thickness of each of the organic layers according to the degree of warpage of the array substrate 100, the required thickness of the focusing layer 200, and the process conditions of organic layer deposition without departing from the spirit and scope of the present disclosure.

Reference is made to FIG. 1A and FIG. 1B. The three micro lenses ML included in the display device 10 are disposed corresponding to the three light-emitting elements 112, respectively. For clarity, the focusing layer 200 is not shown in FIG. 1B.

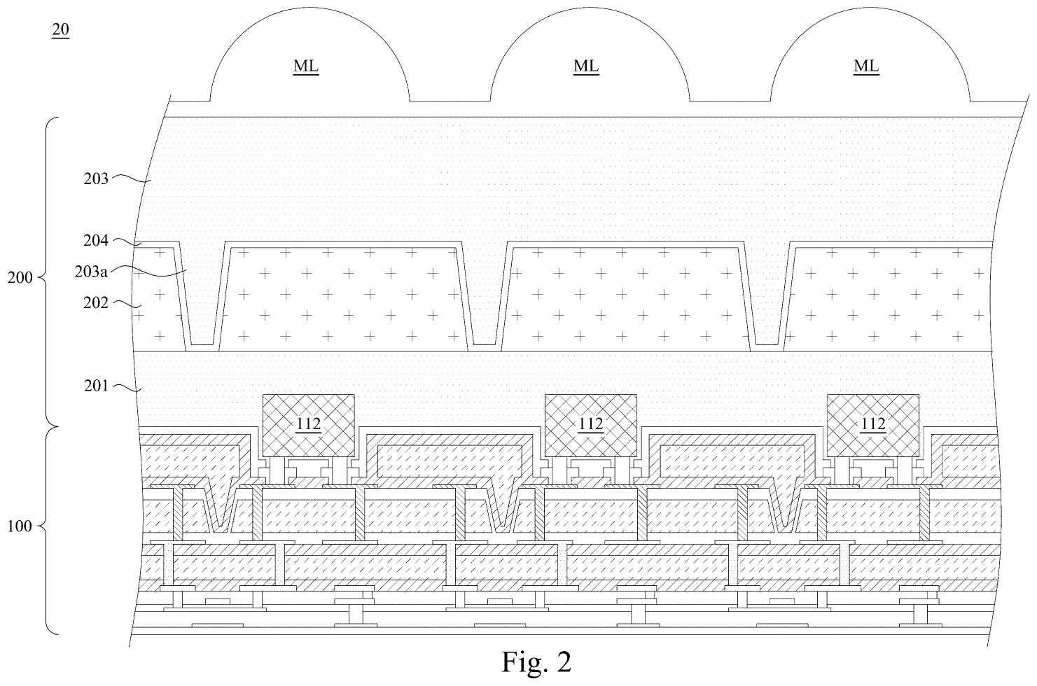

Reference is made to FIG. 2. FIG. 2 is a partial cross-sectional view of a display device 20 according to some embodiments of the present disclosure. As shown in FIG. 2, the difference between the display device 20 and the display device 10 is that the focusing layer 200 of the display device 20 further includes a first insulating layer 204. The first insulating layer 204 covers the second organic layer 202. In greater detail, the first insulating layer 204 is between the second organic layer 202 and the third organic layer 203 and between the extending portions 203a of the third organic layer 203 and the first organic layer 201. In some embodiments, the first insulating layer 204 includes silicon nitride (SiNₓ) or silicon oxide (SiOₓ). Residual compressive stresses usually present within such material layers. For example, a residual tensile stress of a silicon nitride layer or a silicon oxide layer with a film thickness in a range from about 1000 μm to about 2000 μm formed by a single process is about −90 MPa. Therefore, by disposing the first insulating layer 204 between the organic layers, the residual tensile stresses in the organic layers may be offset.

The focal lengths of the micro lenses ML adopted in different display devices may be adjusted in accordance with the light extraction efficiency of the light-emitting elements 112. In such case, the required thickness of the focusing layer 200 may change accordingly. As aforementioned, in order to reduce the residual tensile stresses in the focusing layer 200, the focusing layer 200 may be formed through a series of processes. In addition, an insulating layer with compressive stresses is disposed between the organic layers to further offset the tensile stresses. In greater detail, the organic layer that is in contact with the light-emitting elements 112 and the organic layer that is in contact with the micro lenses ML serve as planarization layers, while other organic layers between the planarization layers may be disposed as discontinuous film structures. The configuration of each portion of the discontinuous film structures may alter based on the required structural strength.

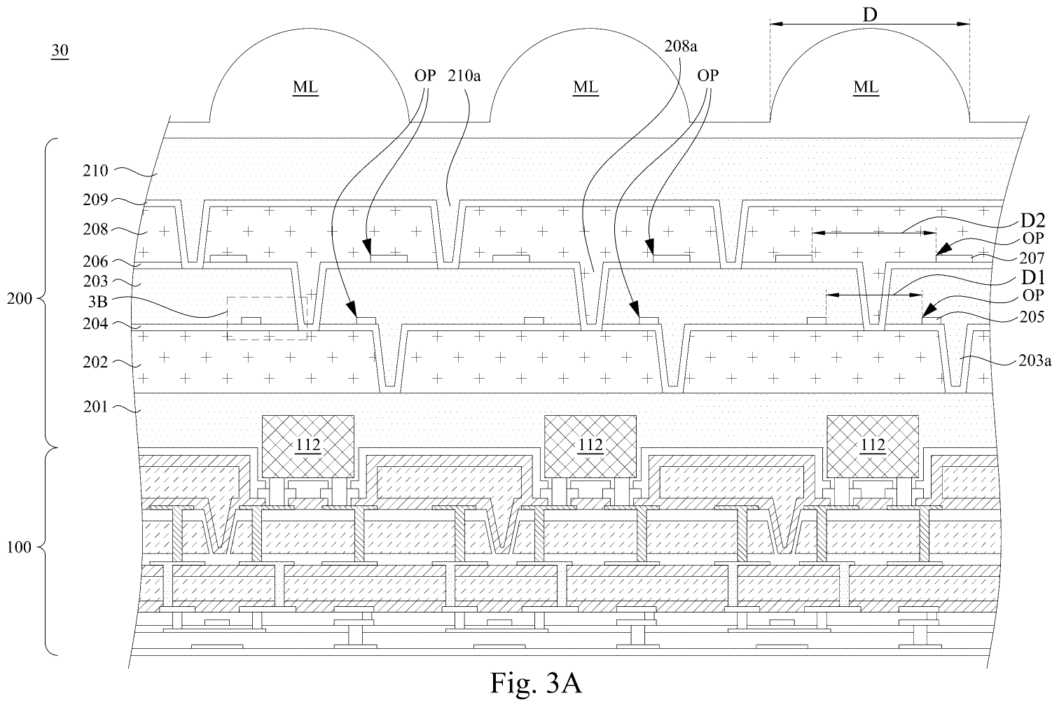

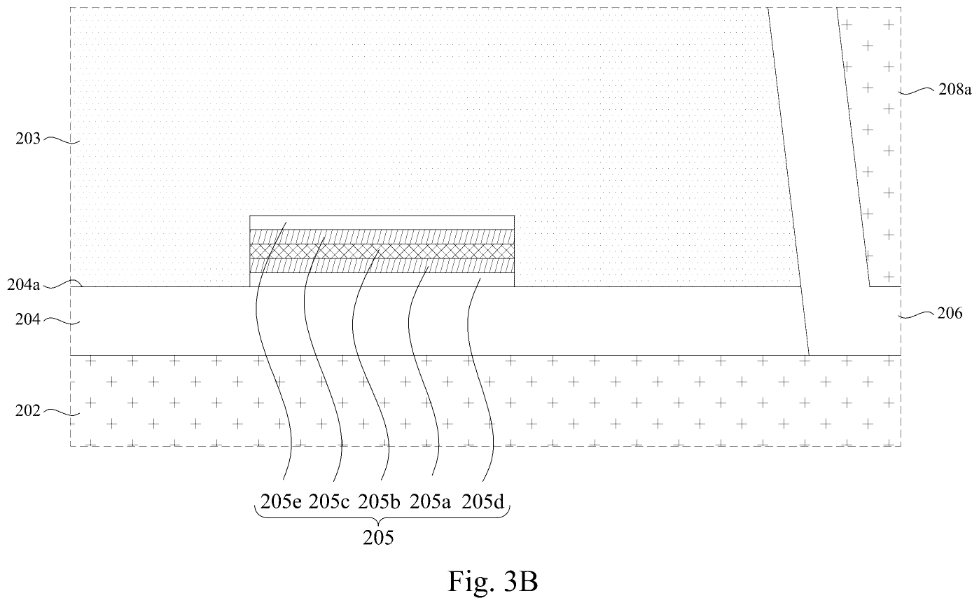

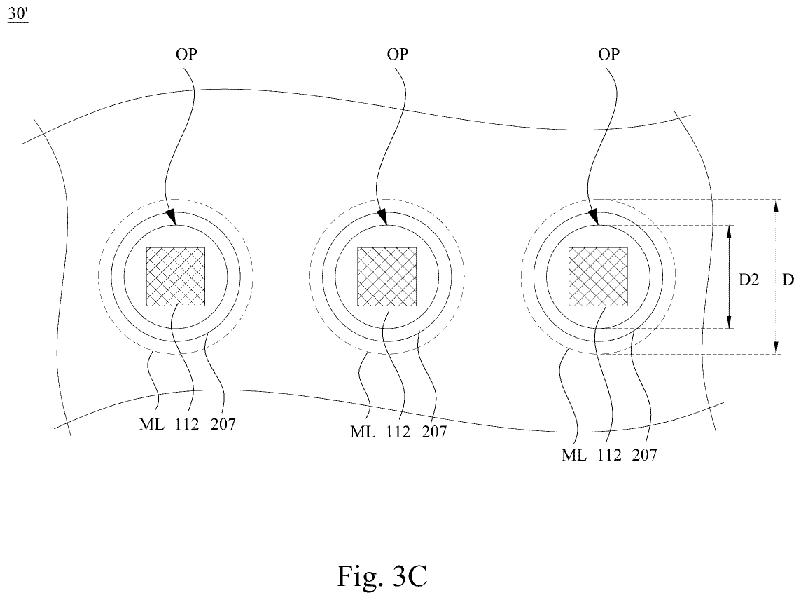

Reference is made to FIG. 3A and FIG. 3B. FIG. 3A is a partial cross-sectional view of a display device 30 according to some embodiments of the present disclosure. FIG. 3B is a partial enlarged view of a square 3B of the display device 30 in FIG. 3A according to some embodiments of the present disclosure. As shown in FIG. 3A, one of the differences between the display device 30 and the display device 20 is that the focusing layer 200 of the display device 30 further includes a second insulating layer 206, a fourth organic layer 208, a third insulating layer 209, and a fifth organic layer 210. Therefore, in the focusing layer 200 of the display device 30, the first organic layer 201 and the fifth organic layer 210 serve as planarization layers, while the second organic layer 202, the third organic layer 203, and the fourth organic layer 208 are disposed as discontinuous film structures. In this way, each of the organic layers can have a smaller film thickness, and more insulating layers with compressive stresses can be disposed between the organic layers.

To be more specific, the fourth organic layer 208 is on the third organic layer 203 and has a plurality of extending portions 208a extending downward through the third organic layer 203, as shown in FIG. 3A. In some embodiments, the extending portions 208a of the fourth organic layer 208 may be in direct contact with the second organic layer 202. In some embodiments, the second insulating layer 206 covers the third organic layer 203. The second insulating layer 206 is between the third organic layer 203 and the fourth organic layer 208 and between the extending portions 208a of the fourth organic layer 208 and the second organic layer 202.

Similarly, as shown in FIG. 3A, the fifth organic layer 210 is on the fourth organic layer 208 and has a plurality of extending portions 210a extending downward through the fourth organic layer 208. In some embodiments, the extending portions 210a of the fifth organic layer 210 may be in direct contact with the third organic layer 203. In some embodiments, the third insulating layer 209 covers the fourth organic layer 208. The third insulating layer 209 is between the fourth organic layer 208 and the fifth organic layer 210 and between the extending portions 210a of the fifth organic layer 210 and the third organic layer 203. The micro lenses ML are on the fifth organic layer 210.

It should be noted that in some embodiments, in order to ensure structure stability of the focusing layer 200, an orthographic projection area of each of the extending portions 203a of the third organic layer 203 projected onto the array substrate 100 is separated from an orthographic projection area of each of the extending portions 208a of the fourth organic layer 208 projected onto the array substrate 100. Similarly, an orthographic projection area of each of the extending portions 208a of the fourth organic layer 208 projected onto the array substrate 100 is separated from an orthographic projection area of each of the extending portions 210a of the fifth organic layer 210 projected onto the array substrate 100.

It should be noted that the orthographic projection area of one of the extending portions 203a and the extending portions 208a projected onto the array substrate 100 may overlap with an orthographic projection area of the light-emitting elements 112 projected onto the array substrate 100.

Next, reference is made to FIG. 3A and FIG. 3B. Another difference between the display device 30 and the display device 20 is that, as shown in FIG. 3A and FIG. 3B, the focusing layer 200 of the display device 30 further includes a first pattern layer 205 on the first insulating layer 204. The purpose of disposing the first pattern layer 205 is to prevent large-angle light emission of the light-emitting elements 112 and to avoid light leakage from the back side of the display device caused by reflection of the large-angle light emission. In addition, color mixing among the light-emitting elements 112 of different colors may be prevented. The first pattern layer 205 includes, for example, three annular patterns (shown as six rectangular cross-sections in the partial cross-sectional view of FIG. 3A). The openings OP of these annular patterns are disposed corresponding to the light-emitting elements 112, respectively. Also, the openings OP correspond to the micro lenses ML, respectively. In order to effectively prevent the large-angle light emission, an inner diameter D1 of each of the annular patterns of the first pattern layer 205 is smaller than a diameter D of its corresponding one of the micro lenses ML. In addition, the inner diameter D1 of each of the annular patterns of the first pattern layer 205 is greater than or equal to a width of its corresponding one of the light-emitting elements 112.

A stacking structure of the first pattern layer 205 is shown in FIG. 3B. The first pattern layer 205 includes a first light-absorbing layer 205a, a light-reflecting layer 205b, and a second light-absorbing layer 205c. As shown in FIG. 3B, the first light-absorbing layer 205a is over the first insulating layer 204. The light-reflecting layer 205b is on the first light-absorbing layer 205a. The second light-absorbing layer 205c is on the light-reflecting layer 205b. The first light-absorbing layer 205a and the second light-absorbing layer 205c are both metal darkening layers with low reflectivity, and the light-reflecting layer 205b is made of metal. For example, the first light-absorbing layer 205a and the second light-absorbing layer 205c may include metal oxides of molybdenum (Mo), tantalum (Ta), niobium (Nb), titanium (Ti), or zinc (Zn), such as molybdenum tantalum oxide (MoTaOₓ). The light-reflecting layer 205b may include metal such as molybdenum. In some embodiments, the first light-absorbing layer 205a has a thickness of about 600 Å, and the light-reflecting layer 205b has a thickness of about 500 Å.

In some embodiments, the first pattern layer 205 further includes a pattern insulating layer 205d and a pattern insulating layer 205e. As shown in FIG. 3B, the pattern insulating layer 205d is between the first insulating layer 204 and the first light-absorbing layer 205a. The pattern insulating layer 205e is on the second light-absorbing layer 205c. By adjusting film thicknesses of the aforementioned layers included in the first pattern layer 205, the first pattern layer 205 may form an interface with low reflectivity and high absorptivity.

It should be noted that in order to simplify the fabrication, a first insulating layer 204 having a greater thickness may be disposed to eliminate the process of forming and patterning the pattern insulating layer 205d. In addition, the process of patterning the pattern insulating layer 205e may be omitted, and the pattern insulating layer 205e may be disposed to fully cover sidewalls of the first light-absorbing layer 205a, the light-reflecting layer 205b, and the second light-absorbing layer 205c as well as an upper surface of the first insulating layer 204.

Reference is made back to FIG. 3A. The focusing layer 200 of the display device 30 further includes a second pattern layer 207 on the second insulating layer 206. Similarly, annular patterns of the second pattern layer 207 are disposed corresponding to the three light-emitting elements 112, respectively, and therefore correspond to the annular patterns of the first pattern layer 205. It should be noted that since a vertical distance between the second pattern layer 207 and the light-emitting elements 112 is greater than a vertical distance between the first pattern layer 205 and the light-emitting elements 112, an inner diameter D2 of each of the annular patterns of the second pattern layer 207 is greater than the inner diameter D1 of its corresponding one of the annular patterns of the first pattern layer 205 and smaller than the diameter D of its corresponding one of the micro lenses ML. In addition, similar to the annular patterns of the first pattern layer 205, the inner diameter D2 of each of the annular patterns of the second pattern layer 207 is greater than or equal to the width of its corresponding one of the light-emitting elements 112.

Reference is made to FIG. 3C. FIG. 3C is a partial top view of the display device 30′ according to some embodiments of the present disclosure. The difference between the display device 30′ and the display device 30 is that the display device 30′ does not include the first pattern layer 205. Therefore, when the organic layer is omitted, the partial top view of the display device 30′ is as shown in FIG. 3C. The inner diameter D2 of each of the annular patterns of the second pattern layer 207 is smaller than the diameter D of its corresponding one of the micro lenses ML and greater than the width of its corresponding one of the light-emitting elements 112.

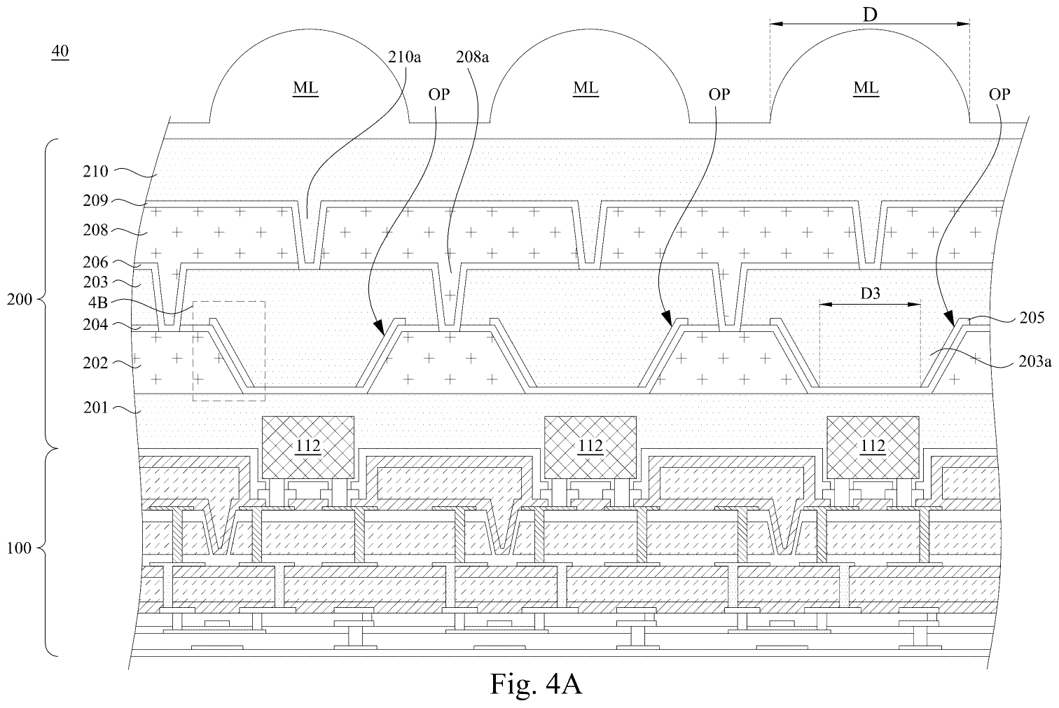

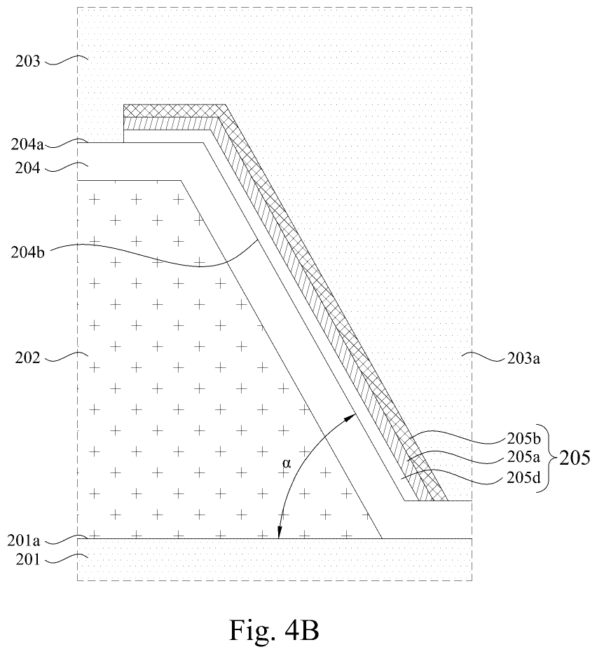

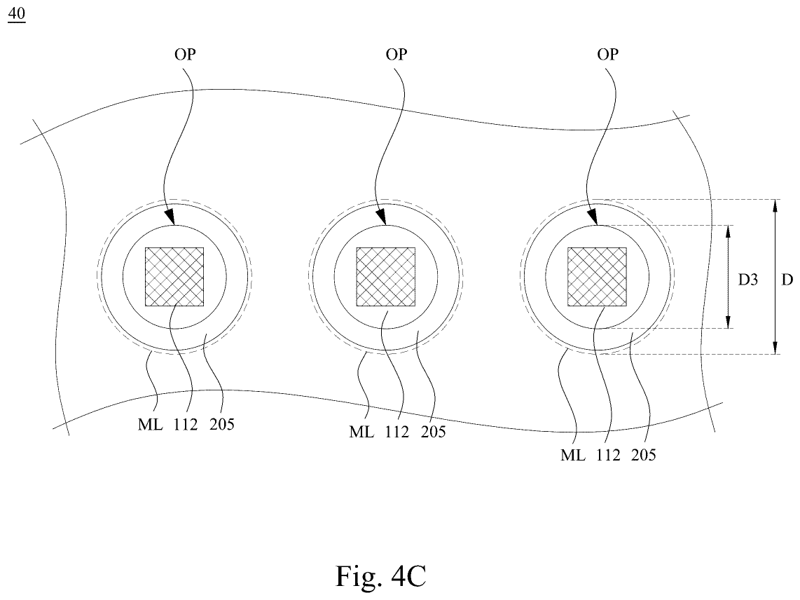

Next, reference is made to FIG. 4A, FIG. 4B, and FIG. 4C. FIG. 4A is a partial cross-sectional view of a display device 40 according to some other embodiments of the present disclosure. FIG. 4B is a partial enlarged view of a square 4B of the display device 40 in FIG. 4A according to some other embodiments of the present disclosure. FIG. 4C is a partial top view of a display device 40 according to some other embodiments of the present disclosure.

As shown in FIG. 4A and FIG. 4B, the difference between the display device 40 and the display device 30 is that the focusing layer 200 of the display device 40 does not include the second pattern layer 207, and the first pattern layer 205 of the display device 40 extend downward from the upper surface 204a of the first insulating layer 204 (as shown in FIG. 4B) along the sidewalls 204b of the first insulating layer 204 (as shown in FIG. 4B). In other words, the first pattern layer 205 is partially between the first insulating layer 204 and the extending portions 203a of the third organic layer 203. At the same time, the openings OP of the annular patterns of the first pattern layer 205 are disposed corresponding to the light-emitting elements 112, respectively. In turn, extending portions 203a of the third organic layer 203 are disposed corresponding to the light-emitting elements 112. In other words, orthographic projection areas of the openings OP and the extending portions 203a projected onto the array substrate 100 overlap with orthographic projection areas of the light-emitting elements 112 projected onto the array substrate 100. As shown in FIG. 4A, an inner diameter D3 of each of the annular patterns of the first pattern layer 205 is greater than the width of its corresponding one of the light-emitting elements 112. Therefore, the orthographic projection areas of the light-emitting elements 112 projected onto the array substrate 100 are within a range of the orthographic projection areas of the openings OP and the extending portions 203a projected onto the array substrate 100.

As such, the first pattern layer 205 can receive a wider range of light emitted by the light-emitting elements 112. Therefore, the side of the first pattern layer 205 facing the third organic layer 203 may be set as an interface having high reflectivity and low absorptivity (for example, reflectivity in a range from about 50% to about 60%) to reflect some of the light with a larger emission angle toward the micro lenses ML to improve the light utilization efficiency. On the other hand, the side of the first pattern layer 205 that is in contact with the first insulating layer 204 may be an interface having low reflectivity and high absorptivity (for example, reflectivity in a range from about 5% to about 6%) to absorb the remaining light with a larger emission angle, preventing reflection that could cause light leakage or color mixing.

To achieve this purpose, a stacking structure of the first pattern layer 205 is as shown in FIG. 4B. The first pattern layer 205 includes a first light-absorbing layer 205a, a light-reflecting layer 205b, and a pattern insulating layer 205d. As shown in FIG. 4B, the pattern insulating layer 205d is on the first insulating layer 204. The first light-absorbing layer 205a is on the pattern insulating layer 205d. The light-reflecting layer 205b is on the first light-absorbing layer 205a. Similarly, the first light-absorbing layer 205a is a metal darkening layer with low reflectivity, and the light-reflecting layer 205b is made of metal. For example, the first light-absorbing layer 205a includes molybdenum tantalum oxide, and the light-reflecting layer 205b includes molybdenum. Similarly, in order to simplify the fabrication, a first insulating layer 204 having a greater thickness may be disposed to eliminate the process of forming and patterning the pattern insulating layer 205d.

In some embodiments, the angle a between the sidewall 204b of the first insulating layer 204 and an upper surface 201a of the first organic layer 201 is in a range from about 50 degrees to about 60 degrees.

Reference is made to FIG. 4A and FIG. 4B. In some embodiments, the inner diameter D3 of each of the annular patterns of the first pattern layer 205 is smaller than the diameter D of its corresponding one of the micro lenses ML and greater than or equal to the width of its corresponding one of the light-emitting elements 112, as shown in FIG. 4A. By adjusting the extent to which the first pattern layer 205 covers the sidewall 204b, the inner diameter D3 can be changed, thereby modifying the light reception range of the first pattern layer 205. In some embodiments, the first pattern layer 205 extends from the upper surface 204a of the first insulating layer 204 to cover a part of the sidewall 204b. The relative positions and dimensions of the annular patterns of the first pattern layer 205, the micro lenses ML, and the light-emitting elements 112 are shown in FIG. 4C.

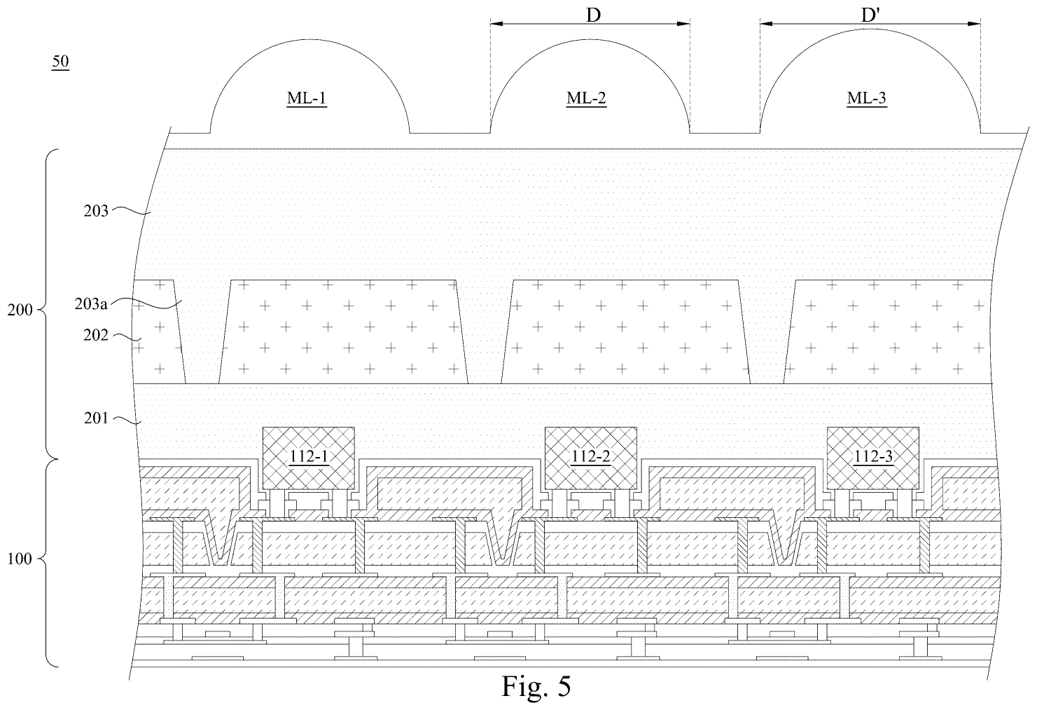

Reference is made to FIG. 5. FIG. 5 is a partial cross-sectional view of a display device 50 according to some embodiments of the present disclosure. In some embodiments, the display device 50 includes a plurality of micro light-emitting diodes with different colors of light. Since the micro light-emitting diodes of different colors have different light extraction efficiencies, their corresponding micro lenses ML may have different diameters. For example, in some embodiments, the light-emitting element 112-1 corresponding to the micro lens ML-1 is a red light-emitting diode. The light-emitting element 112-2 corresponding to the micro lens ML-2 is a green light-emitting diode. The light-emitting element 112-3 corresponding to the micro lens ML-3 is a blue light-emitting diode. The light extraction efficiency of the blue light-emitting diode is smaller than the light extraction efficiency of the red light-emitting diode and the light extraction efficiency of the green light-emitting diode. Therefore, as shown in FIG. 5, the micro lens ML-3 has a diameter D′ that is greater than the diameter D.

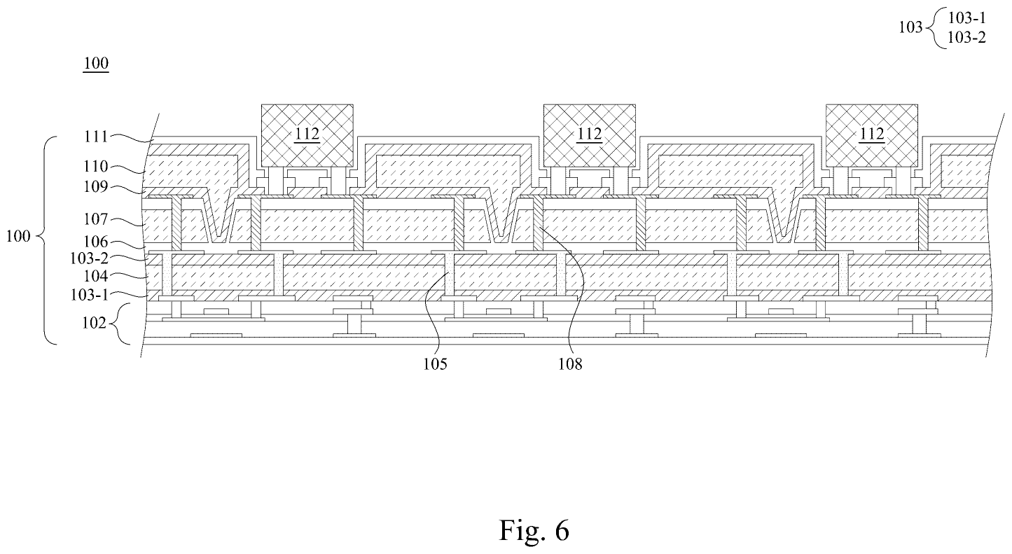

Reference is made to FIG. 6. FIG. 6 is a partial cross-sectional view of the array substrate 100 according to some embodiments of the present disclosure. As shown in FIG. 6, the array substrate 100 includes a circuit substrate 102, a first passivation layer 104, a first metal layer 105, a second passivation layer 107, a second metal layer 108, and a third passivation layer 110. The first passivation layer 104 is over the circuit substrate 102. The first metal layer 105 is over the first passivation layer 104. The first metal layer 105 has a portion extending downward through the first passivation layer 104 and is electrically connected to the circuit substrate 102. The second passivation layer 107 covers the first metal layer 105 and the first passivation layer 104. The second metal layer 108 is over the second passivation layer 107. The second metal layer 108 has a portion extending downward through the second passivation layer 107 and is electrically connected to the first metal layer 105. The third passivation layer 110 covers the second metal layer 108 and has a portion extending downward through the second passivation layer 107. In some embodiments, the light-emitting elements 112 are on the second metal layer 108 and are electrically connected to the second metal layer 108.

As aforementioned, the array substrate included in the backplane may include thick coppers with residual tensile stresses, such as the first metal layer 105 and the second metal layer 108 of the array substrate 100. At the same time, the passivation layers of the array substrate may include organic materials with residual tensile stresses. For example, the first passivation layer 104, the second passivation layer 107, and the third passivation layer 110 may include a positive photoresist of acrylic series materials. Therefore, in some embodiments of the present disclosure, the array substrate 100 further includes a film layer with residual compressive stresses to reduce the degree of warpage of the array substrate. As shown in FIG. 6, the array substrate 100 further includes a fourth insulating layer 103, a fifth insulating layer 106, a sixth insulating layer 109, and a seventh insulating layer 111. These insulating layers may include silicon nitride or silicon oxide. In addition, in terms of the fabrication, the metal layers and the passivation layers may be deposited in layers to reduce the generation of residual tensile stress.

It should be noted that in the array substrate 100, each of the insulating layers is divided into two portions. Taking the fourth insulating layer 103 as an example, as shown in FIG. 6, the fourth insulating layer 103 may be divided into two portions: a fourth insulating layer 103-1 and a fourth insulating layer 103-2. The fourth insulating layer 103-1 fully covers the metal lines of the circuit substrate 102 and is under the first passivation layer 104 to increase adhesion of the first passivation layer 104. The fourth insulating layer 103-2 covers the first passivation layer 104 and is under the first metal layer 105 for lapping of the first metal layer 105, as shown in FIG. 6.

In addition, the passivation layers of the array substrate 100 may be disposed as discontinuous film structures to release tensile stresses. For example, FIG. 6 illustrates the second passivation layer 107 being a discontinuous film structure.

According to the foregoing recitations of the embodiments of the disclosure, it may be seen that in the display device of some embodiments of the present disclosure, the focusing layer includes a plurality of layers of thin films formed through a series of processes. At least one discontinuous film structure is included in the focusing layer, thereby reducing residual tensile stresses developed in the focusing layer due to the manufacturing processes without affecting the optical properties of the focusing layer. At the same time, an insulating layer with compressive stresses may be disposed in the focusing layer to further offset the residual tensile stresses. Compared with common display devices, the display device of some embodiments of the present disclosure may experience reduced tensile stresses while maintaining the required thickness of the focusing layer, avoiding warpage of the display device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A display device, comprising:
an array substrate having a plurality of light-emitting elements disposed thereon;
a first organic layer on the array substrate and covering the light-emitting elements;
a second organic layer on the first organic layer;
a third organic layer on the second organic layer, wherein the third organic layer has a portion extending downward through the second organic layer; and
a plurality of micro lenses over the third organic layer and disposed corresponding to the light-emitting elements, respectively.

2. The display device of claim 1, further comprising a first insulating layer covering the second organic layer, wherein the first insulating layer is between the second organic layer and the third organic layer and between the portion of the third organic layer and the first organic layer.

3. The display device of claim 2, further comprising a pattern layer on the first insulating layer, wherein the pattern layer has a plurality of annular patterns, the annular patterns have a plurality of openings, respectively, each of the openings has an inner diameter smaller than a diameter of at least one of the micro lenses, and each of the annular patterns comprises:
a first light-absorbing layer over the first insulating layer; and
a light-reflecting layer on the first light-absorbing layer.

4. The display device of claim 3, wherein each of the annular patterns further comprises a second light-absorbing layer on the light-reflecting layer.

5. The display device of claim 3, wherein the annular patterns extend downward from an upper surface of the first insulating layer along a plurality of sidewalls of the first insulating layer, and the openings of the annular patterns correspond to the light-emitting elements, respectively.

6. The display device of claim 1, further comprising a fourth organic layer on the third organic layer, wherein the fourth organic layer has a portion extending downward through the third organic layer.

7. The display device of claim 6, further comprising a second insulating layer covering the third organic layer, wherein the second insulating layer is between the third organic layer and the fourth organic layer and between the portion of the fourth organic layer and the second organic layer.

8. The display device of claim 6, wherein an orthographic projection area of the portion of the third organic layer projected onto the array substrate is separated from an orthographic projection area of the portion of the fourth organic layer projected onto the array substrate.

9. The display device of claim 1, wherein the array substrate comprises:
a circuit substrate;
a first passivation layer on the circuit substrate;
a first metal layer on the first passivation layer, wherein the first metal layer has a portion extending downward through the first passivation layer and electrically connected to the circuit substrate;
a second passivation layer covering the first metal layer and the first passivation layer;
a second metal layer on the second passivation layer, wherein the second metal layer has a portion extending downward through the second passivation layer and electrically connected to the first metal layer; and
a third passivation layer covering the second metal layer and having a portion extending downward through the second passivation layer.

10. The display device of claim 9, wherein the array substrate further comprises a first insulating layer covering the second passivation layer, wherein the first insulating layer is between the second passivation layer and the third passivation layer and between the portion of the third passivation layer and the first passivation layer.

11. A display device, comprising:
an array substrate having a light-emitting element disposed thereon;
a focusing layer over the array substrate and comprising:
a first organic layer covering the light-emitting element;
a second organic layer over the first organic layer and having a plurality of portions separated from one another; and
a third organic layer over the second organic layer and having an extending portion between two adjacent ones of the portions of the second organic layer; and
a micro lens over the third organic layer and over the light-emitting element.

12. The display device of claim 11, wherein the extending portion of the third organic layer is in contact with the first organic layer.

13. The display device of claim 11, wherein the focusing layer further comprises a first insulating layer covering the second organic layer, wherein the first insulating layer is between the portions of the second organic layer and the extending portion of the third organic layer.

14. The display device of claim 13, wherein the first insulating layer is partially in contact with the first organic layer.

15. The display device of claim 13, wherein the focusing layer further comprises a first pattern layer on the first insulating layer, wherein the first pattern layer has an annular pattern, and the annular pattern has an inner diameter smaller than a diameter of the micro lens.

16. The display device of claim 15, wherein the annular pattern of the first pattern layer extends downward from an upper surface of the first insulating layer along a sidewall of the first insulating layer.

17. The display device of claim 15, wherein the focusing layer further comprises a second pattern layer over the third organic layer, wherein the second pattern layer has an annular pattern, and the annular pattern of the second pattern layer has an inner diameter smaller than the diameter of the micro lens and greater than the inner diameter of the annular pattern of the first pattern layer.
